(19) United States
(12) Patent Application Publication
(10) Pub. No.: US 2026/0165184 A1
(43) Pub. Date: Jun. 11, 2026

(54) SEMICONDUCTOR DEVICE

(71) Applicant: RENESAS ELECTRONICS CORPORATION, Tokyo (JP)

(72) Inventor: Mitsunobu WANSAWA, Tokyo (JP)

(21) Appl. No.: 19/408,542

(22) Filed: Dec. 4, 2025

(30) Foreign Application Priority Data
Dec. 6, 2024 (JP) 2024-213186

(51) Int. Cl. H10W 72/90

(52) U.S. Cl. CPC H10W 72/9223; H10W 72/932; H10W 72/936; H10W 72/942

(57) ABSTRACT

A semiconductor device includes: a plurality of pads; a plurality of redistribution wirings connected to the plurality of pads; a terminal provided on a land portion of each of the plurality of redistribution wirings; and a conductive film connected to each of the terminal and the land portion. The plurality of redistribution wirings includes: a first redistribution wiring having a first land portion; and a second redistribution wiring having a second wiring portion. A planar shape of the conductive film is circular. A planar shape of the first land portion is non-circular. In plan view, the first land portion is arranged adjacent to the second wiring portion which is extending in the Y direction. In plan view, the first land portion has a first side which is linearly extending along the second wiring portion.

### CROSS-REFERENCE TO RELATED APPLICATIONS

The disclosure of Japanese Patent Application No. 2024-213186 filed on Dec. 6, 2024, including the specification, drawings and abstract is incorporated herein by reference in its entirety.

### BACKGROUND

The present invention relates to a semiconductor device.

There are disclosed techniques listed below.
[Patent Document 1] Japanese Unexamined Patent Application Publication No. 2010-278040
[Patent Document 2] Japanese Unexamined Patent Application Publication No. 2017-183571
[Patent Document 3] Japanese Unexamined Patent Application Publication No. 2012-191123

There is a semiconductor device in which a pad provided on a peripheral portion of a semiconductor chip is connected to a solder ball via a redistribution wiring (Patent Document 1). In the semiconductor device disclosed in Patent Document 1, a plurality of solder balls is arranged in a lattice pattern. Also, there is a semiconductor device in which a conductive layer is arranged between a land portion of a redistribution wiring and a solder ball (Patent Document 2). Furthermore, there is a semiconductor device in which a plurality of redistribution wirings is arranged between terminals which are adjacent to each other (Patent Document 3).

### SUMMARY

As the functionality of the semiconductor device becomes high, the number of terminals in one semiconductor device tends to increase. However, due to the demand for miniaturization of the semiconductor device, the mounting area of the semiconductor device cannot be increased even if the number of terminals increases. As a result, the technique for arranging the redistribution wiring electrically connecting the pad of the semiconductor chip and the terminal in high density is required.

Other challenges and novel features will become apparent from the description of this specification and the accompanying drawings.

A semiconductor device according to one embodiment, includes: a plurality of pads; a plurality of redistribution wirings connected to the plurality of pads; a terminal provided on a land portion of each of the plurality of redistribution wirings; and a conductive film connected to each of the terminal and the land portion. The plurality of redistribution wirings includes: a first redistribution wiring having a first land portion; and a second redistribution wiring having a second wiring portion. A planar shape of the conductive film is circular. A planar shape of the first land portion is non-circular. In plan view, the first land portion is arranged adjacent to the second wiring portion which is extending in the Y direction. In plan view, the first land portion has a first side which is linearly extending along the second wiring portion.

According to the embodiment, the performance of the semiconductor device can be improved.

### BRIEF DESCRIPTION OF THE DRAWINGS

FIG. 1 is a plan view of a mounting surface of a semiconductor device according to one embodiment.

FIG. 2 is a cross-sectional view along line A-A of FIG. 1.

FIG. 3 is an enlarged plan view of portion B shown in FIG. 1.

FIG. 4 is an enlarged cross-sectional view along line C-C of FIG. 3.

FIG. 5 is an enlarged plan view showing a modified example of FIG. 3.

FIG. 6 is an enlarged plan view showing another modified example of FIG. 3.

FIG. 7 is an enlarged plan view showing a region shown in FIG. 3 and its surrounding region.

FIG. 8 is an enlarged cross-sectional view along line D-D of FIG. 7.

FIG. 9 is an enlarged plan view showing an outline of a conductive layer arranged on a land portion and an outline of a solder ball arranged on the conductive layer, in the enlarged plan view shown in FIG. 3.

### DETAILED DESCRIPTION

### Description of Format, Basic Term, and Usage in the Present Application

In the present application, the description of the embodiments is divided into multiple sections for convenience. These are not mutually independent and separate, but one is a detailed part of the other, or one is a modified example of the other. In principle, descriptions of similar parts are omitted. Furthermore, each component in the embodiments is not essential unless it is clearly indicated as an essential component, is theoretically limited to that number, or is clearly essential from the context.

Similarly, in the description of embodiments, etc., regarding materials, compositions, etc., even if it is stated as “X consisting of A”, unless it is clearly limited or clearly limited from the context, elements other than A are not excluded. For example, regarding components, it means “X containing A as the main component”. For example, even if it is stated as “silicon member”, it is not limited to pure silicon but also includes SiGe (silicon-germanium) alloys and other multi-component alloys with silicon as the main component, and other additives. Similarly, even if it is stated as gold plating, Cu layer, nickel plating, etc., unless otherwise specified, it includes members with gold, Cu, nickel, etc., as the main component, not just pure ones.

Furthermore, when specific numerical values or quantities are mentioned, unless they are clearly limited or clearly limited from the context, those specific numerical values are described as examples.

In the drawings of the embodiments, the same or similar parts are denoted by the same or similar symbols or reference numerals, and the description will not be repeated in principle.

In the attached drawings, hatching and the like may be omitted even in a cross-section when it becomes complicated or when it is clearly distinguished from a gap. In this connection, even if the hole is closed in plan, the outline of the background may be omitted when it is obvious from the description or the like. Furthermore, even if it is not a cross-section, hatching or dot patterns may be added to indicate that it is not a gap or to indicate the boundary of a region.

### Semiconductor Device

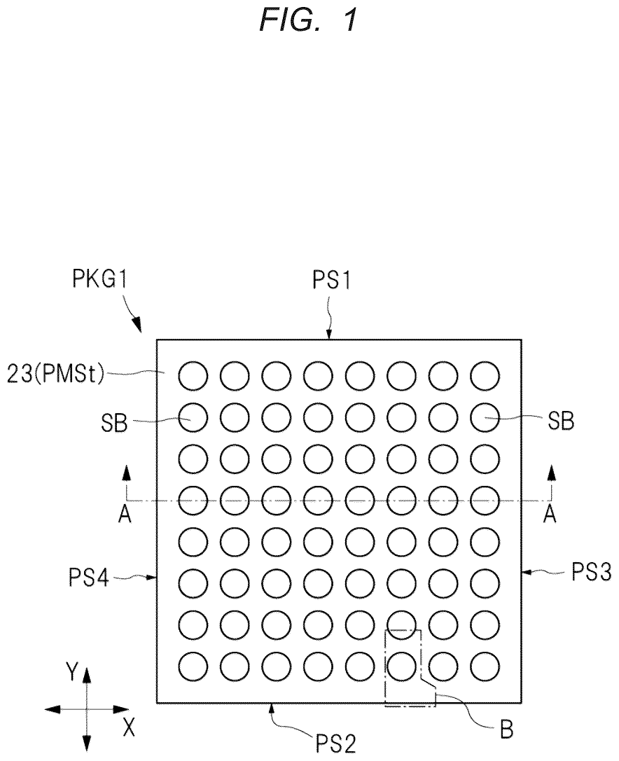

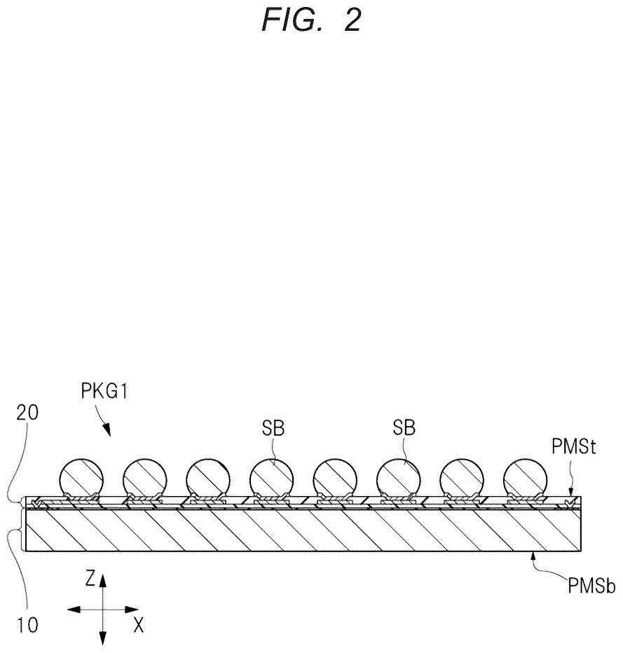

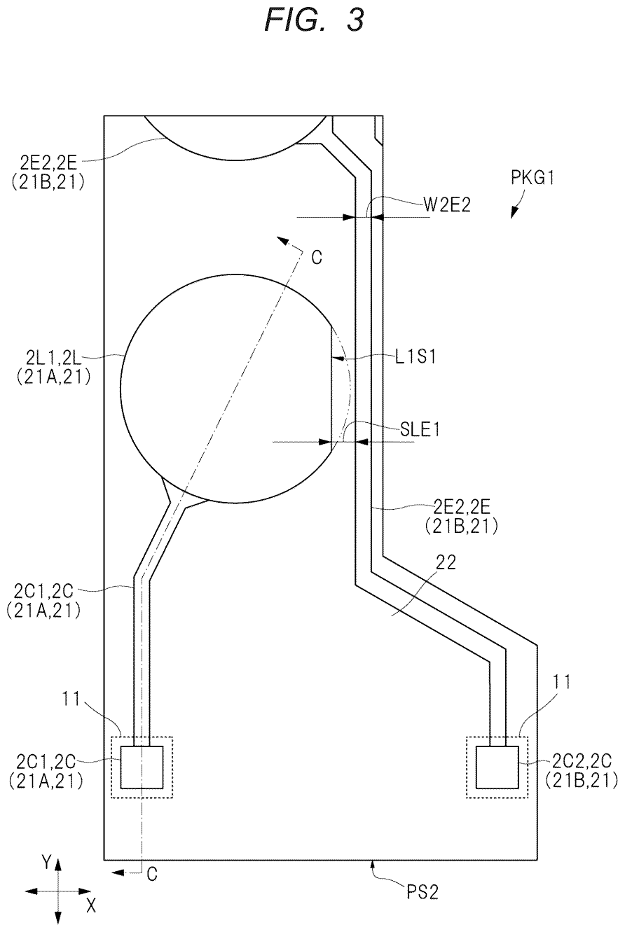

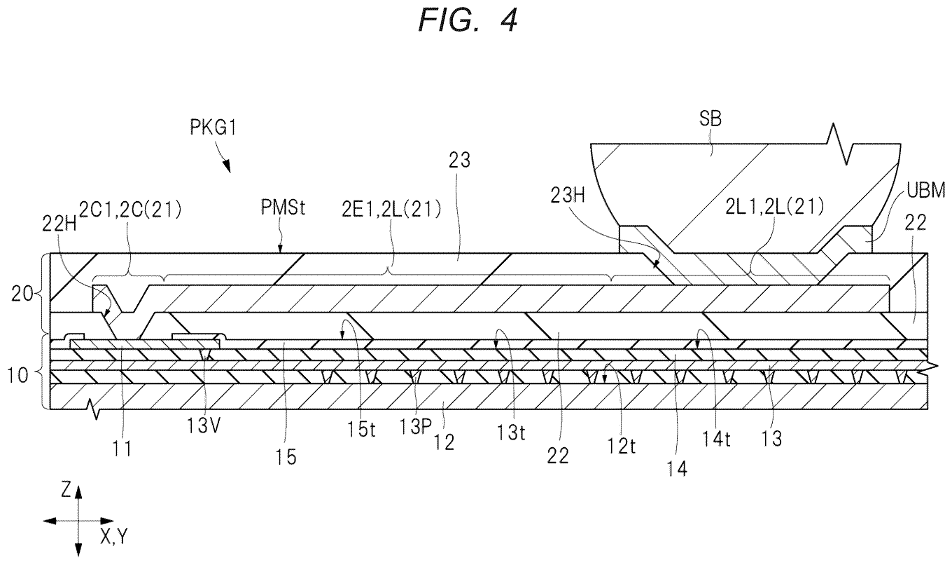

First, the semiconductor device of the present embodiment will be described. FIG. 1 is a plan view of the mounting surface of the semiconductor device of the present embodiment. FIG. 2 is a cross-sectional view along line A-A of FIG. 1. FIG. 3 is an enlarged plan view showing an example of redistribution wiring in portion B shown in FIG. 1. In FIG. 3, the outline of pad 11 is shown with a dotted line. FIG. 4 is an enlarged cross-sectional view along line C-C of FIG. 3.

In FIGS. 1 to 3, either the X direction (see FIGS. 1 to 3), the Y direction (see FIGS. 1 and 3), or the Z direction (see FIG. 2) is described. The Y direction is a direction crossing the X direction. In the following description, the X direction and the Y direction are perpendicular to each other. The Z direction is a direction perpendicular to each of the X direction and the Y direction. In other words, the Z direction is the normal direction (in other words, the vertical direction) to the X-Y plane including the X direction and the Y direction. In the following description, “thickness” means the length in the Z direction in principle. Also, in the following description, “plan view” means a plan view seen from the X-Y plane in principle.

In the present embodiment, a semiconductor device applying a redistribution wiring technology, where the terminal is provided at a position different from the electrode pad of the semiconductor chip in plan view by forming a redistribution layer on a semiconductor chip, is described. As an example, a semiconductor package referred to as “WPP” or “WLCSP” is described.

The semiconductor device PKG1 shown in FIG. 1 has a main surface PMSt and a main surface PMSb (see FIG. 2) located opposite to the main surface PMSt. In plan view, the main surface PMSt forms a rectangle. Specifically, the main surface PMSt includes a side PS1 extending in the X direction, a side PS2 located opposite to side PS1, a side PS3 extending in the Y direction crossing the X direction, and a side PS4 located opposite to side PS3. The side PS1 intersects with each of sides PS3 and PS4, and the side PS2 intersects with each of sides PS3 and PS4.

The semiconductor device PKG1 has a plurality of terminals (external terminals, protruding electrodes) SB arranged on the main surface PMSt. In the present embodiment, each of the plurality of terminals SB is a solder ball that is made of solder material and that is shaped into a ball shape. Although a solder ball is taken as an example of the terminal SB in the semiconductor device PKG1, there are various modifications to the structure of the terminal SB. For instance, a columnar conductor (pillar bump) formed in a columnar shape may be used. In the case of a columnar conductor, for example, a solder layer is laminated on the tip of a columnar conductor mainly composed of copper (Cu).

In the example shown in FIG. 1, the plurality of terminals SB is arranged along the X and Y directions. A semiconductor device like PKG1 in which a plurality of external terminals is arranged on the main surface PMSt is called an area array type semiconductor device. An area array type semiconductor device is mounted in a state where the main surface PMSt faces the mounting surface of a mounting substrate not shown in the figure. In this case, the mounting area of the semiconductor device can be reduced, and the number of terminals can be increased.

In the example shown in FIG. 1, the semiconductor device PKG1 has a total of 64 terminals SB arranged in 8 rows and 8 columns. However, the number of terminals SB is not limited to 64, and there are various modifications. Regarding the number of arrangements, there are various modifications other than the mode shown in FIG. 1. Although not shown, for example, there may be a total of 90 terminals SB arranged in 10 rows and 9 columns, or more terminals SB.

As shown in FIG. 2, the semiconductor device PKG1 includes a semiconductor chip 10 and a rewiring portion 20 formed on the semiconductor chip 10. The semiconductor chip 10 includes, for example, a plurality of semiconductor elements such as transistors and diodes, and a plurality of pads 11 (see FIG. 4) electrically connected to the plurality of semiconductor elements. The rewiring portion 20 is disposed between the plurality of terminals SB and the semiconductor chip 10 and includes a redistribution wiring 21 (see FIG. 4) that electrically connects the semiconductor chip 10 and the terminals SB. The semiconductor device PKG1 with the rewiring portion 20 can arrange the terminal SB at a position different from the pad 11 of the semiconductor chip 10 in plan view.

In the semiconductor device with the rewiring portion 20 which is arranged on the semiconductor chip 10 as shown in the present embodiment, the rewiring portion 20 is formed in the wafer process before obtaining the semiconductor chip by singulating the semiconductor wafer. Therefore, it is called WPP (Wafer Process Package). Also, the semiconductor device of the present embodiment is obtained by singulating the semiconductor wafer in which the rewiring portion is formed. In this case, the planar size of the semiconductor device PKG1 is approximately the same as the planar size of the semiconductor chip 10. A package where the planar size of the semiconductor device is approximately the same as the planar size of the semiconductor chip is called WLCSP (Wafer Level Chip Scale Package).

WLCSP is a semiconductor device that has the advantage of a small planar size, in other words, a small mounting area. Therefore, even if the number of terminals provided in WLCSP is increased along with the higher functionality of the semiconductor device, it is necessary to suppress the increase in the planar size of WLCSP accordingly. Thus, in WLCSP, a technology to improve the arrangement density of the conductor pattern in the redistribution section is required.

The semiconductor chip 10 shown in FIG. 4 has a semiconductor substrate 12 made of a semiconductor material such as silicon (Si). The semiconductor substrate 12 is the base material of the semiconductor chip 10 and the semiconductor device PKG1. The semiconductor substrate 12 also has a semiconductor element forming surface (main surface) 12t, on which the aforementioned semiconductor elements are formed. Although not shown in FIG. 4, the semiconductor substrate 12 also has a main surface opposite to the semiconductor element forming surface 12t. The main surface opposite the semiconductor element forming surface 12t is the same surface as the main surface PMSb shown in FIG. 2.

On the semiconductor element forming surface 12t, wiring layers (chip wiring layers) 13 and insulating films 14 are alternately laminated. The wiring layer 13 is made of, for example, copper or a copper alloy containing copper as the main component. The insulation film 14 is an insulating film (inorganic insulating film) made of an inorganic insulating material such as silicon dioxide (SiO2).

The wiring layer 13 is electrically connected to the semiconductor element forming surface 12t of the semiconductor substrate 12 via a plug 13P. The wiring layer 13 is also electrically connected to a pad (electrode pad) 11 via a via wiring 13V. That is, the wiring layer 13 is a conductive path for electrically connecting the semiconductor elements formed on the semiconductor element forming surface 12t and the pad 11. Note that each of the wiring layers 13 and the insulating film 14 is not limited to a single layer, and a plurality of wiring layers 13 and a plurality of insulating films 14 may be alternately laminated.

Each of the plurality of pads 11 of the semiconductor chip 10 is formed on the insulating film 14 (the uppermost insulating film 14 in the case where the plurality of layers is laminated). The pad 11 is made of, for example, aluminum. Considering the versatility of the semiconductor chip 10, it is preferable that, for example, a wire not shown can be bonded to the pad 11 for use. When bonding a wire, it is preferable that the pad 11 is made of aluminum.

Each of the plurality of pads 11 formed on the main surface 13t of the wiring layer 13 is made of aluminum. An insulating film 15 is also formed on the main surface 13t. The insulating film 15 is an insulating film (passivation film) that protects the main surface 13t of the wiring layer 13 of the semiconductor chip 10. The insulation film 15 is an inorganic insulating film made of an inorganic insulation material such as silicon dioxide (SiO2) or silicon nitride (SiN), or a laminated film of these.

The insulating film 15 overlaps a peripheral portion of the pad 11. An opening is formed in the insulating film 15. The central portion of pad 11 is exposed from the insulating film 15 at the opening of the insulating film 15. The portion of the pad 11 exposed from the insulating film 15 functions as a terminal of the semiconductor chip 10. For example, in this embodiment, the portion of the pad 11 exposed from the insulating film 15 is connected to the contact portion 2C1 of the redistribution wiring 21.

As shown in FIG. 3, the plurality of pads 11 is arranged along the edge of the periphery of the main surface PMSt. In the example shown in FIG. 3, the plurality of pads 11 are arranged along the side PS2. Although not shown, in the case of the semiconductor device PKG1, the plurality of pads 11 (see FIG. 3) are arranged along each of the sides PS2, PS3, and PS4 shown in FIG. 1. However, in some cases, pads 11 are arranged along only some of the sides PS1, PS2, PS3, and PS4 shown in FIG. 1.

The main circuit (core circuit) provided in the semiconductor chip 10 is arranged at a position overlapping the central region of the main surface PMSt shown in FIG. 1. On the other hand, the input/output circuit including the plurality of pads 11 is arranged at a position overlapping the peripheral region of the main surface PMSt. In the case of the semiconductor device PKG1, each of the plurality of terminals SB is arranged in a region inside the plurality of pads 11 in plan view. However, as a modification, some of the plurality of terminals SB may be arranged at a position overlapping the pads 11 or at a position outside the pads 11.

In this embodiment, the plurality of pads 11 is arranged only in the peripheral region of the main surface PMSt. By connecting the redistribution wiring 21 (see FIG. 3) to each of the plurality of pads 11, the plurality of terminals SB provided in the semiconductor device PKG1 can be arranged in a grid pattern. The rewiring portion 20 (see FIG. 4) is a member for arranging the terminals SB at positions different from the positions of pads 11 of the semiconductor chip 10 in plan view.

As shown in FIG. 4, the terminal SB and the pad 11 are electrically connected to each other via the redistribution wiring 21 of the rewiring portion 20. The rewiring portion 20 includes the redistribution wiring 21, an insulating film 22 formed on the insulating film 15 of the semiconductor chip 10, and an insulating film 23 formed on the insulating film 22. The redistribution wiring 21 is formed on the insulating film 22. However, a portion of the contact portion 2C1 of the redistribution wiring 21 is connected to the pad 11 without the insulating film 22. The redistribution wiring 21 is also covered by the insulating film 23.

The terminal SB is provided via a conductive film (under bump metal, conductive layer) UBM on the land portion 2L1 of the redistribution wiring 21. The conductive film UBM is a conductive film formed between the terminal SB and the land portion 2L1 and connected to each of the terminal SB and the land portion 2L1.

The redistribution wiring 21 is a metal pattern made of, for example, copper or a copper alloy. The redistribution wiring 21 is made of a metal film laminated on a seed layer (not shown) formed on the insulating film 22, for example.

In FIG. 4, the stack of the aforementioned seed layer and metal film is illustrated as the redistribution wiring 21.

The conductive film UBM is an intermediate layer positioned between the terminal SB and the land portion 2L1, as described above. By using material for the conductive film UBM that has higher connectivity to solder than the land portion 2L1, the connection reliability between the terminal SB and the redistribution wiring 21 can be improved.

Additionally, by using a material with high solder barrier properties as the conductive film UBM, it is possible to suppress the diffusion of solder from the terminal SB. Metals that can be exemplified as constituting the conductive film UBM with the above characteristics include nickel or gold. Furthermore, the conductive film UBM may be a laminated film of the plurality of layers of metal films.

The insulating film 22 forms the base layer of the redistribution wiring 21. It is made of organic material with a lower dielectric constant than the insulating film 15, which is made of inorganic material. In the present embodiment, the insulating film 22 is made of, for example, polyimide resin. By using an organic insulating film as the insulating film 22, it is possible to reduce the parasitic capacitance formed between the redistribution wiring 21 and the wiring layer 13.

The insulating film 22 includes an opening 22H that penetrates the insulating film 22 in the thickness direction. The contact portion 2C1 of the redistribution wiring 21 is embedded in the opening 22H. Additionally, the opening 22H is formed on pad 11. A portion of the pad 11 is exposed from the insulating film 22 at the opening 22H. This configuration allows the contact portion 2C1 and the pad 11 to be electrically connected.

The insulating film 23 is formed to cover the redistribution wiring 21 and functions as a protective film to protect the redistribution wiring 21. The insulating film 23 is made of an organic insulating film such as a polyimide film. The insulating film 23 has the main surface PMSt of the semiconductor device PKG1. By using an organic insulating film for the insulating film 23, it is possible to improve adhesion with the insulating film 22.

Furthermore, the insulating film 23 includes an opening 23H that penetrates the insulating film 23 in the thickness direction. The conductive film UBM is embedded in the opening 23H. Additionally, the opening 23H is formed on the land portion 2L of the redistribution wiring 21. A portion of the land portion 2L is exposed from the insulating film 23 at the opening 23H. This configuration allows the conductive film UBM and the land portion 2L to be electrically connected.

As shown in FIG. 3, the redistribution wiring 21A includes a contact portion 2C1 electrically connected to the pad 11. The redistribution wiring 21A includes a land portion 2L1 connected to terminal SB via the conductive film UBM. The redistribution wiring 21A includes a wiring portion 2E1 that connects the contact portion 2C1 and the land portion 2L1.

As shown in FIG. 4, the contact portion 2C1 is arranged on pad 11. The land portion 2L1 is a part for connecting terminal SB and is arranged at a position away from the contact portion 2C1. As shown in FIG. 3, the wiring portion 2E1 is a part routed to connect the contact portion 2C1 and the land portion 2L1. The wiring portion 2E1 is an extending portion patterned in a strip shape.

Additionally, as shown in FIG. 3, the redistribution wiring 21B includes a contact portion 2C2, a land portion 2L2, and a wiring portion 2E2. That is, each of a plurality of redistribution wirings 21 includes a contact portion 2C, a land portion 2L, and a wiring portion 2E.

Here, as shown in FIG. 3, the wiring portion 2E of each of the plurality of redistribution wirings 21 extends inward from a peripheral portion of the semiconductor device PKG1. If the number of terminals SB of the semiconductor device PKG1 is to be increased, the number of land portions 2L and wiring portions 2E increases, making it easy for areas with high local density of land portions 2L and wiring portions 2E to occur.

In the example shown in FIG. 3, assuming the shape of the land portion 2L1 of the redistribution wiring 21A is circular, as indicated by the two-dot chain line, there may be areas where the separation distance between the land portion 2L1 and the wiring portion 2 E2 becomes extremely small. In this case, there is a concern about short circuits between the redistribution wiring 21A and the redistribution wiring 21B, or mutual interference between the current flowing through the redistribution wiring 21A and the current flowing through the redistribution wiring 21B may become an issue.

Therefore, in the case of the semiconductor device PKG1 of this embodiment, as shown in FIG. 3, the land portion 2L1 is arranged adjacent to the wiring portion 2E2 which is extending in the Y direction. The land portion 2L1 also has a side L1S1 which is linearly extending along the wiring portion 2E2.

By providing the side L1S1 which is linearly extending along the wiring portion 2E2 in the part of the outer edge of the land portion 2L1 adjacent to the wiring portion 2E2, it is possible to sufficiently secure the separation distance SLE1 between the land portion 2L1 and the wiring portion 2E2.

For example, in the example shown in FIG. 3, the value of the separation distance SLE1 between the land portion 2L1 and the wiring portion 2E2 is equal to or greater than the value of the width W2E2 (the length in the X direction perpendicular to the Y direction which is the extending direction) of the wiring portion 2E2.

The minimum value of the separation distance SLE1 is defined by design rules. The design rules are determined by considering whether the degree of interference occurring between electrically separated and adjacently arranged transmission paths is within an acceptable range, among other factors. Hereinafter, the minimum value of the separation distance SLE1 and the like defined by the design rules will be referred to as the “design minimum value”.

In the example of the present embodiment, each of the side L1S1 and the wiring portion 2E2 extends in the Y direction. In other words, it is particularly preferable for the side L1S1 and the wiring portion 2 E2 to be parallel to each other from the perspective of ensuring that the value of the separation distance SLE1 is at least the design minimum value. However, even if the side L1S1 and the wiring portion 2E2 are not parallel, it is acceptable as long as the value of the separation distance SLE1 is at least the design minimum value.

Note that the value of the width W2E2 is determined by product specifications, so there are various modified examples depending on the product specifications. For example, if the product specifications require the value of the width W2E2 to be extremely large, there may be cases where the value of the separation distance SLE1 is smaller than the value of the width W2E2.

However, even in this case, as already mentioned, by providing the side L1S1, it is possible to increase the value of the separation distance SLE1 between the land portion 2L1 and the wiring portion 2E2. Therefore, according to this embodiment, it is possible to set the value of the separation distance SLE1 to a value (i.e., the design minimum value) that does not cause mutual interference between the current flowing through the redistribution wiring 21A and the current flowing through the redistribution wiring 21B.

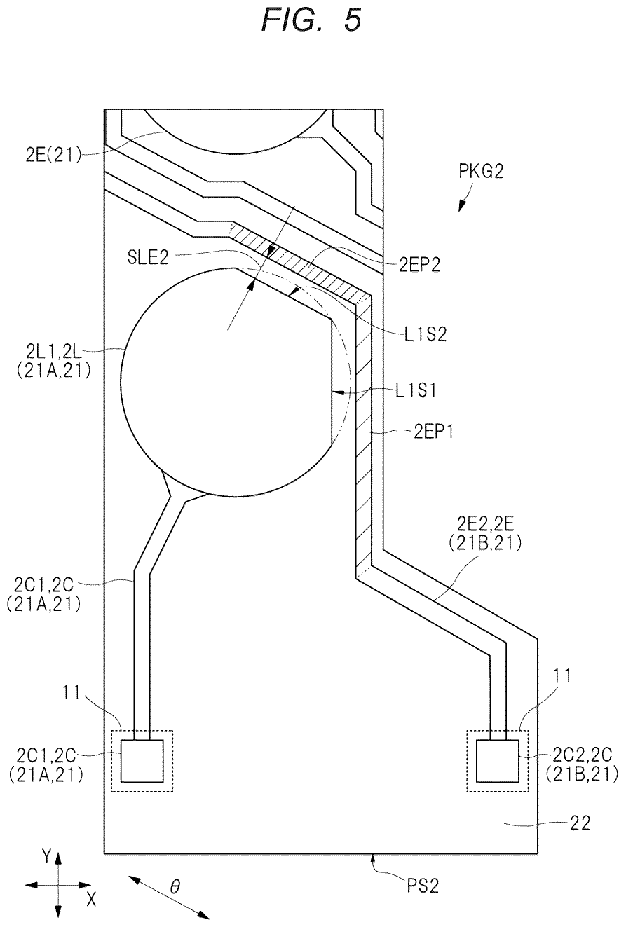

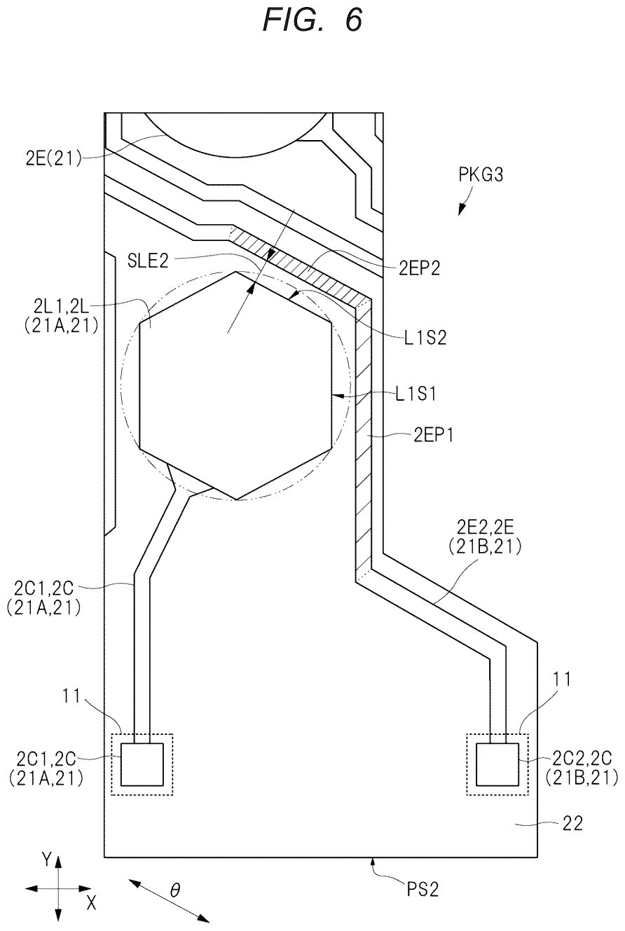

Meanwhile, in the example shown in FIG. 1, the wiring portion 2E2 linearly extends in the Y direction near the land portion 2L1, but there is also a part which is extending in the direction different from the Y direction at the position away from the land portion 2L1. Depending on the layout of the wiring portion 2E2, it may be preferable for the land portion 2L1 to have plural sides each linearly extending. FIG. 5 is an enlarged plan view showing a modified example of FIG. 3. FIG. 6 is an enlarged plan view showing another modified example of FIG. 3.

The semiconductor device PKG2 shown in FIG. 5 differs from the semiconductor device PKG1 shown in FIG. 3 in the following points. In the modified example shown in FIG. 5, the wiring portion 2E2 of the redistribution wiring 21B includes a portion 2EP1 which is extending in the Y direction and a portion 2EP2 which is extending in the θ direction crossing the X direction. The land portion 2L1 is arranged adjacent to the portion 2EP1 of the wiring portion 2E2 and has a side L1S1 which is linearly extending along the portion 2EP1 of the wiring portion 2E2 and is arranged adjacent to the portion 2EP2 of the wiring portion 2E2 and has a side L1S2 which is linearly extending along the portion 2EP2 of the wiring portion 2E2.

In the case of the semiconductor device PKG2, by having the side L1S2 in the land portion 2L1, it is possible to adjust the value of the separation distance SLE2 between the land portion 2L1 and the portion 2EP2 of the wiring portion 2E2 of the redistribution wiring 21B. Therefore, for example, it is possible to set the value of the separation distance SLE2 to a value (i.e., the design minimum value) that does not cause mutual interference between the current flowing through the redistribution wiring 21A and the current flowing through the redistribution wiring 21B.

Additionally, in the example shown in FIG. 5, it is preferable for the side L1S1 and the portion 2EP1 of the wiring portion 2E2 to be parallel to each other. In other words, it is preferable for each of the sides L1S1 and the portion 2EP1 of the wiring portion 2E2 to linearly extend in the Y direction. Similarly, it is preferable for the side L1S2 and the portion 2EP2 of the wiring portion 2E2 to be parallel to each other. In other words, it is preferable for each of the side L1S2 and the portion 2EP2 of the wiring portion 2E2 to linearly extend in the θ direction.

The semiconductor device PKG3 shown in FIG. 6 differs from the semiconductor device PKG1 shown in FIG. 3 in the following aspects. Specifically, the planar shape of the land portion 2L1 included in the semiconductor device PKG3 is polygonal. In the example shown in FIG. 6, the planar shape of the land portion 2L1 is hexagonal. Besides the hexagonal shape shown in FIG. 6, the planar shape of the land portion 2L1 can have various modifications. Depending on the direction in which the wiring portion 2E2 adjacent to the land portion 2L1 extends, it can be, for example, pentagonal, heptagonal, or octagonal.

Although details will be described later, from the perspective of preventing peeling at the adhesion interface with the insulating film 22 or insulating film 23 that adheres closely to the land portion 2L shown in FIG. 4, it is preferable to avoid stress concentration occurring on a part of the outer periphery of the land portion 2L. In the case of a polygon, stress may concentrate at multiple vertices. From the perspective of equalizing the stress concentrated at each vertex, it is preferable for the planar shape of the land portion 2L to be a regular polygon. Moreover, if the interior angle of the polygon (i.e., the land portion formed in a polygonal shape) is acute (i.e., less than 90 degrees), stress concentration is likely to occur at the vertex. Therefore, it is preferable for each of the interior angles of the land portion formed in a polygonal shape to be greater than 90 degrees.

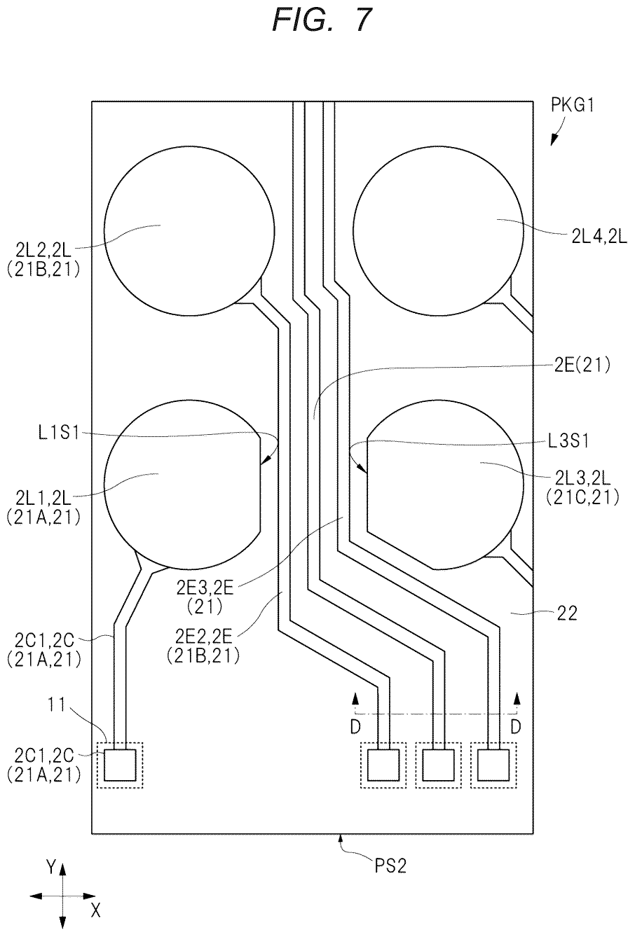

Next, the advantages of having a circular planar shape for the land portion 2L will be explained. As shown in FIG. 4, land portion 2L adheres closely to both the insulation film 22 and the insulating film 23. Here, attention is focused on preventing peeling at the adhesion interface between the land portion 2L and the insulating film 22, as well as between the land portion 2L and the insulating film 23. FIG. 7 is an enlarged plan view showing the region shown in FIG. 3 and its surrounding area.

The peeling of the adhesion interface mentioned above occurs due to stress arising from the difference in linear expansion coefficients of each member. Particularly, if stress concentration occurs at a specific point on the outer periphery of the land portion 2L, the point where stress concentration occurs becomes the starting point of peeling. Furthermore, once a starting point of peeling occurs, peeling progresses along the adhesion interface where the starting point exists.

Therefore, from the perspective of preventing peeling of the adhesion interface, it is preferable to suppress the occurrence of stress concentration. When the planar shape of the land portion 2L is circular, stress concentration is less likely to occur. If the occurrence of stress concentration can be suppressed, the starting point of the aforementioned peeling is less likely to occur. If the starting point of peeling does not occur, the progression of peeling will not occur either. In other words, when the planar shape of the land portion 2L is circular, it is preferable in that it can suppress peeling of the adhesion interface caused by the difference in linear expansion coefficients between the land portion 2L and the insulating film 22 (or insulating film 23).

As shown in FIG. 7, in plan view, the land portion 2L2 of the redistribution wiring 21B is positioned farther from the outer edge of the semiconductor device PKG1 (for example, the side PS2 shown in FIG. 7) than the land portion 2L1. The planar shape of the land portion 2L2 is circular.

In the case of the present embodiment, where the arrangement density of the plurality of redistribution wirings 21 is high, the planar shape of the land portion 2L is non-circular, and thus, allowing the separation distance between the redistribution wirings which are adjacent to each other to be at least the design minimum value. On the other hand, even when the planar shape of the land portion 2L is circular, in the region where the separation distance between the redistribution wirings which are adjacent to each other can be at least the design minimum value, the planar shape of the land portion 2L is circular.

As shown in FIG. 7, the plurality of pads 11 is arranged along the outer periphery of the semiconductor device PKG1. Each of the plurality of redistribution wirings 21 has a contact portion 2C along the outer periphery of the semiconductor device PKG1. Additionally, a plurality of land portions 2L is arranged inside (closer to the center of the semiconductor device PKG1) than a plurality of contact portions 2C. Therefore, focusing on the arrangement density of a plurality of wiring portions 2E, the following can be said.

That is, in plan view, the arrangement density of the plurality of wiring portions 2E is low near the center of the semiconductor device PKG1, and high near the outer periphery of the semiconductor device PKG1.

Therefore, in the case of the present embodiment, the shape of the land portion 2L1, where the arrangement density of the wiring portion 2E is relatively high, is non-circular, and the shape of the land portion 2L2, where the arrangement density of the wiring portion 2E is relatively low, is circular.

As a result, in the land portion 2L2, it is possible to suppress peeling of the adhesion interface caused by the difference in linear expansion coefficients between the land portion 2L2 and the insulating film 22 (or insulating film 23) shown in FIG. 4. Peeling between the redistribution wiring 21 and the insulating film 22 (or insulating film 23) becomes a particular problem if it progresses over a wide range, but if it remains within a local range, the impact is small. In the case of the present embodiment, the planar shape of the land portion 2L is selectively made non-circular in regions where the arrangement density of the wiring portion 2E is particularly high, while in other regions, the planar shape of the land portion 2L is circular. This reduces the number of points that can become the starting point of peeling, thereby suppressing the widespread progression of peeling.

Furthermore, among the plurality of land portions 2L, the number of wiring portions 2E arranged between the land portion 2L1 and the land portion 2L3, which are arranged on the outermost periphery, tends to be large (three in the example shown in FIG. 7). On the other hand, the number of wiring portions 2E arranged between the land portion 2L2 and the land portion 2L4, which are arranged in the second row from the outermost periphery, is smaller compared to the land portions 2L arranged on the outermost periphery (two in the example shown in FIG. 7).

For example, consider the 64 land portions 2L (see FIG. 3) arranged directly below each of the plurality of terminals SB shown in FIG. 1. In the case of the present embodiment, the planar shape of the land portions 2L arranged in the second row and beyond from the outermost periphery can be circular. The planar shape of the 28 land portions 2L arranged on the outermost periphery is non-circular, and the 36 land portions 2L arranged in the second row and beyond are circular. In other words, among the plurality of land portions 2L included in the semiconductor device PKG1, the number of land portions 2L with a circular planar shape is greater than the number of land portions 2L with a non-circular planar shape.

Additionally, as an indicator of high arrangement density of the wiring portion 2E, it can be expressed using the number of wiring portions 2E arranged between adjacent land portions 2L. For example, in the example shown in FIG. 7, it can be expressed as follows.

That is, the plurality of redistribution wirings 21 includes a redistribution wiring 21C that includes the land portion 2L3 arranged next to the land portion 2L1 among the plurality of land portions 2L formed on the insulating film 22 (see FIG. 4). The land portion 2L1 and the land portion 2L3 are adjacent to each other in the X direction which is the extending direction of the side PS2.

In plan view, three or more wiring portions 2E, including the wiring portion 2E2, are formed between the land portion 2L1 and the land portion 2L3. In the example shown in FIG. 7, it is preferable for at least one of the planar shapes of the land portions 2L adjacent to each other via three or more wiring portions 2E to be non-circular.

In the example shown in FIG. 7, both planar shapes of the land portions 2L adjacent to each other via three or more wiring portions 2E are non-circular. Specifically, the three or more wiring portions 2E are electrically separated from each of the land portions 2L1 and 2L3 and include a wiring portion 2E3 extending in the Y direction. The land portion 2L3 is arranged adjacent to the wiring portion 2E3 and has a side L3S1 which is linearly extending along the wiring portion 2E3.

According to the present embodiment, since the arrangement density of the redistribution wiring 21 can be improved, the number of terminals per unit area can be increased. For example, if all the increased terminals by applying the present embodiment are used as signal transmission terminals, the number of signal transmission terminals per unit area can be increased.

Additionally, in the example shown in FIG. 7, two wiring portions 2E are arranged between the land portion 2L2 and the land portion 2L4, which are adjacent to each other in the X direction. In FIG. 7, when the number of wiring portions 2E arranged between adjacent land portions 2L is two or less, the separation distance between the wiring portion 2E and the land portion 2L can be at least the design minimum value even if the planar shape of the land portion 2L is not non-circular.

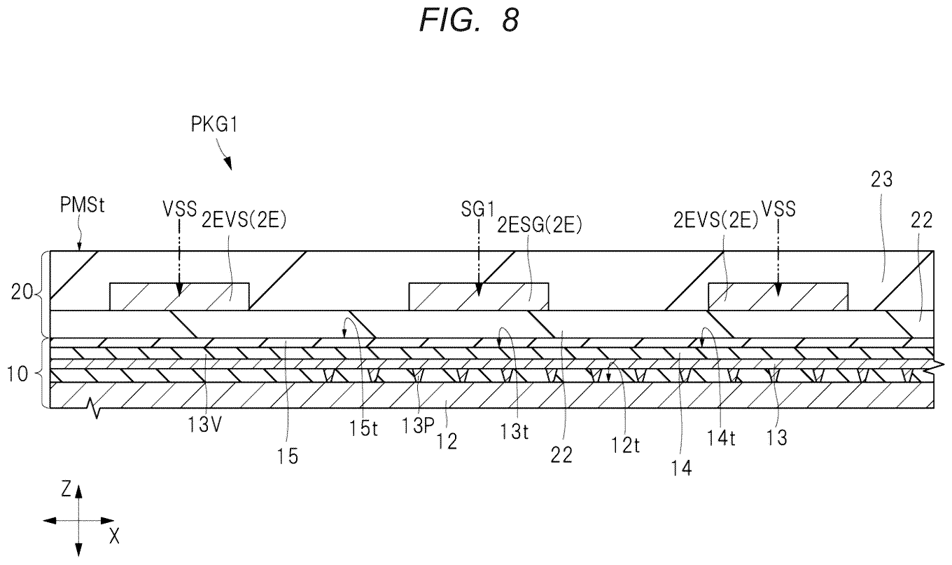

Furthermore, from the perspective of improving the quality of signals flowing through the signal transmission path, the following configuration is preferable. FIG. 8 is an enlarged cross-sectional view along line D-D of FIG. 7. In FIG. 8, the signals or reference potentials flowing through each wiring portion are schematically illustrated using arrows with dashed lines.

In FIG. 7, the three wiring portions 2E arranged between the land portion 2L1 and the land portion 2L3 include a signal wiring portion 2ESG through which the signal SG1 is transmitted, as shown in FIG. 8, and are arranged adjacent to the signal wiring portion 2ESG. Additionally, the three wiring portions 2E include two reference potential wiring portions 2EVS through which the reference potential VSS is transmitted.

The reference potential VSS is a fixed potential. In the example of the present embodiment, the reference potential VSS is, for example, a ground potential. As shown in FIG. 8, the structure in which the reference potential wiring portions 2EVS are arranged on both sides of the signal wiring portion 2ESG is called a coplanar structure, and each of the reference potential wiring portions 2EVS functions as an electromagnetic shield.

For example, electromagnetic noise directed towards the signal wiring portion 2ESG is attenuated by the reference potential wiring portions 2EVS. Therefore, the signal transmission path including the signal wiring portion 2ESG becomes less susceptible to external electromagnetic noise. In other words, the reference potential wiring portions 2EVS functions as an electromagnetic shield that suppresses the intrusion of external electromagnetic noise into the signal transmission path including the signal wiring portion 2ESG.

Also, for example, electromagnetic noise generated in the signal wiring portion 2ESG is attenuated by the reference potential wiring portions 2EVS. That is, the reference potential wiring portions 2EVS function as an electromagnetic shield that suppresses the influence of electromagnetic noise generated in the signal wiring portion 2ESG on the surrounding signal transmission paths.

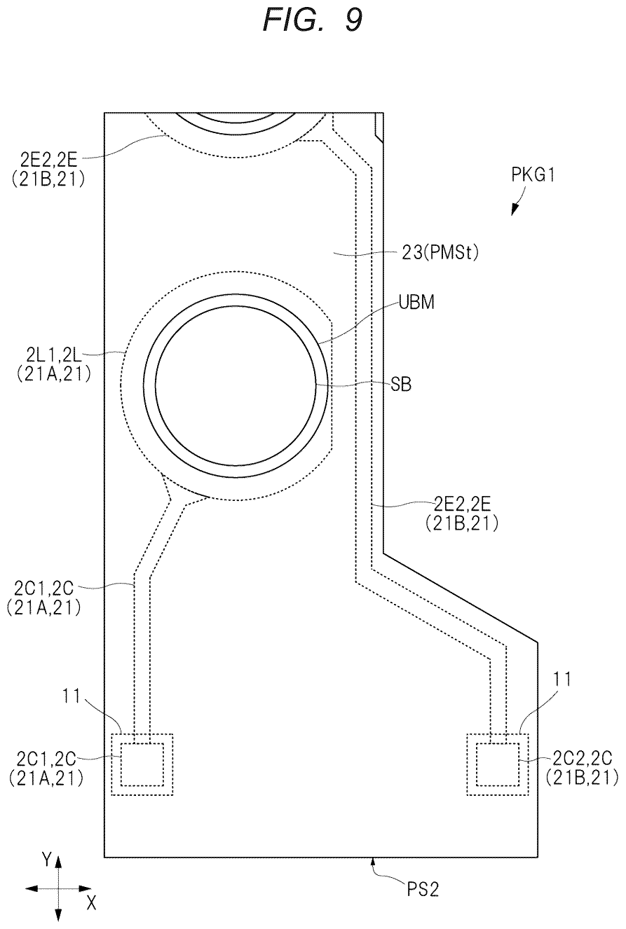

Next, a preferred embodiment of the conductive film UBM shown in FIG. 4 will be described. FIG. 9 is an enlarged plan view showing the outline of the conductive layer arranged on the land portion and the outline of the solder ball arranged on the conductive layer, in the enlarged plan view shown in FIG. 3.

As shown in FIG. 9, in plan view, the planar shape of the conductive film UBM is circular. Also, the planar shape of the terminal SB is circular. In plan view, the diameter of the terminal SB is smaller than the diameter of the conductive film UBM.

As already described, the shape of the land portion 2L1 is non-circular. Although the planar shape of the conductive film UBM may be non-circular following the shape of the land portion 2L1, it is preferably circular as shown in FIG. 9.

As shown in FIG. 4, the lower surface of the conductive film UBM is in close contact with the insulating film 23. Here, from the viewpoint of suppressing the peeling of the adhesion interface between the conductive film UBM and the insulating film 23, it is preferable to avoid local concentration of stress on a part of the outer edge of the conductive film UBM.

As in the case of the planar shape of the land portion 2L already described, in the case of the conductive film UBM, by making the planar shape circular, stress concentration can be suppressed. As a result, it is possible to prevent local concentration of stress on a part of the outer edge of the conductive film UBM, thereby suppressing the peeling of the adhesion interface between the conductive film UBM and the insulating film 23.

Also, in the example shown in FIG. 9, the entire conductive film UBM overlaps with land portion 2L1. In plan view, the land portion 2L1 is larger than the conductive film UBM. By increasing the planar area of the land portion 2L1, stress can be dispersed at the outer edge of the land portion 2L1. As a result, it is possible to prevent peeling at the adhesion interface between the land portion 2L and the insulating film 22, and between the land portion 2L and the insulating film 23, as shown in FIG. 4.

Although the invention made by the present inventor has been specifically described based on the embodiment, the present invention is not limited to the above embodiment, and needless to say that various modifications can be made without departing from the gist thereof.

For example, in the above embodiment, an embodiment was described in which the planar shape of some of the plurality of land portions 2L is non-circular, and the planar shape of other portions is circular. However, as a modified example, there may be cases where the planar shape of all the plurality of land portions 2L is non-circular.

Also, in the example described using FIG. 7, the planar shape of the land portion 2L1 and the planar shape of the land portion 2L3 are each non-circular but have different planar shapes from each other. However, as a modified example, there may be cases where each of the plurality of land portions 2L with non-circular planar shapes has the same shape as each other.

Also, for example, there may be a case where the modified examples described above are combined with each other.

What is claimed is:

1. A semiconductor device comprising:
a first insulating film;
a plurality of pads formed on the first insulating film;
a second insulating film formed on the first insulating film and overlapping a peripheral portion of each of the plurality of pads;
a plurality of redistribution wirings formed on the second insulating film;
a terminal provided on a land portion of each of the plurality of redistribution wirings; and
a conductive film formed between the terminal and the land portion, and connected to each of the terminal and the land portion,
wherein the plurality of pads include: a first pad; and a second pad,
wherein the plurality of redistribution wirings include:
a first redistribution wiring having: a first contact portion arranged on the first pad and connected to the first pad; a first land portion arranged at a position situated away from the first contact portion; and a first wiring portion located between the first contact portion and the first land portion; and
a second redistribution wiring having: a second contact portion arranged on the second pad and connected to the second pad; a second land portion arranged at a position situated away from the second contact portion; and a second wiring portion located between the second contact portion and the second land portion,
wherein a planar shape of the conductive film connected to the first land portion is circular,
wherein a planar shape of the first land portion is non-circular,
wherein in plan view, the first land portion is arranged adjacent to the second wiring portion which is extending in a first direction, and
wherein in plan view, the first land portion has a first side which is linearly extending along the second wiring portion.

2. The semiconductor device according to claim 1,
wherein the second wiring portion includes:
a first portion which is extending in the first direction; and
a second portion which is extending in a second direction crossing the first direction,
wherein the first side extends along the first portion of the second wiring portion, and
wherein in plan view, the first land portion has:
the first side arranged adjacent to the first portion of the second wiring portion and linearly extending along the first portion of the second wiring portion; and
a second side arranged adjacent to the second portion of the second wiring portion and linearly extending along the second portion of the second wiring portion.

3. The semiconductor device according to claim 2, wherein the planar shape of the first land portion is polygonal.

4. The semiconductor device according to claim 3, wherein each of interior angles of the first land portion formed in a polygonal shape is greater than 90 degrees.

5. The semiconductor device according to claim 2,
wherein the first side and the first portion of the second wiring portion are parallel to each other, and
wherein the second side and the second portion of the second wiring portion are parallel to each other.

6. The semiconductor device according to claim 1,
wherein in plan view, the second land portion is located at a position far away from an outer edge of the semiconductor device than the first land portion,
wherein a planar shape of the conductive film connected to the second land portion is circular, and
wherein a planar shape of the second land portion is circular.

7. The semiconductor device according to claim 1,
wherein the plurality of redistribution wirings further includes a third redistribution wiring, the third redistribution wiring having a third land portion arranged adjacent to the first land portion in plan view,
wherein in plan view, three or more wiring portions, which are including the second wiring portion, of the plurality of redistribution wirings are arranged between the first land portion and the third land portion, and
wherein in plan view, the second wiring portion is a wiring portion located closest to the first land portion among the three or more wiring portions.

8. The semiconductor device according to claim 7,
wherein the three or more wiring portions are electrically isolated from each of the first land portion and the third land portion,
wherein the three or more wiring portions include a third wiring portion which is extending in the first direction,
wherein in plan view, the third land portion is arranged adjacent to the third wiring portion,
wherein in plan view, the third land portion has a third side which is linearly extending along the third wiring portion, and
wherein in plan view, the third wiring portion is a wiring portion located closest to the third land portion among the three or more wiring portions.

9. The semiconductor device according to claim 7, wherein the three or more wiring portions include:
a signal wiring portion through which a signal is transmitted, and
two reference potential wiring portions arranged on both sides of the signal wiring portion, and through which a reference potential is transmitted.
